(19) United States
(12) Patent Application Publication
(10) Pub. No.: US 2016/0027946 A1
(43) Pub. Date: Jan. 28, 2016

(54) OPTICAL DEVICE

(71) Applicant: JSR CORPORATION, TOKYO (JP)

(72) Inventor: HIROAKI TOKUHISA, TOKYO (JP)

(21) Appl. No.: 14/877,919

(22) Filed: Oct. 7, 2015

Related U.S. Application Data
(63) Continuation of application No. PCT/JP2014/052347, filed on Jan. 31, 2014.

(30) Foreign Application Priority Data
Apr. 12, 2013 (JP) 2013-084260

(51) Int. Cl. H01L 31/055; C09K 19/56; H01L 31/054; G02F 1/1337; G02F 1/1335

(52) U.S. Cl. CPC H01L 31/055; G02F 1/1337; G02F 1/133524; G02F 1/133711; H01L 31/0547; C09K 19/56

(57) ABSTRACT

An optical device is described, including a switching layer that includes an anisotropic light-emitting material for absorbing and radiating light and switches alignment of the light-emitting material, an alignment layer in contact with the switching layer, an optical energy conversion means that converts the radiated light into at least one energy form selected from heat and electricity, and a light guide system that is in physical contact with the optical energy conversion means and guides the radiated light to the optical energy conversion means. The switching layer controls transmission of light through the optical device. The alignment layer includes 80 wt % or more of a polyorganosiloxane.

### CROSS-REFERENCE TO RELATED APPLICATION

This application is a bypass continuation application of and claims the priority benefit of the International PCT application serial no. PCT/JP2014/052347, filed on Jan. 31, 2014, which claims the priority benefit of Japan application serial no. 2013-084260, filed on Apr. 12, 2013. The entirety of each of the above-mentioned patent applications is hereby incorporated by reference herein and made a part of this specification.

### FIELD OF THE INVENTION

The invention relates to an optical device, and more specifically, to an optical device including an anisotropic light-emitting material.

### DESCRIPTION OF THE RELATED ART

As an optical device, e.g., a window having a liquid crystal layer, in which alignment of a switching layer depends on a supplied voltage, is disclosed in Patent Document 1. In one embodiment, the switching layer includes a liquid crystal dye. In addition, e.g., a window including a fluorescent layer is disclosed in Patent Document 2. The light radiated from the fluorescent layer is totally reflected and guided to a photovoltaic cell. Patent Document 3 discloses a light-emitting material including light-emitting material molecules, and a cholesteric layer, wherein the light-emitting material molecules are statically aligned in a different layer.

Patent Document 4 discloses a laser oscillation device using a liquid crystal and an organic fluorescent material. Inside the laser oscillation device, light is guided between surfaces of mirrors and exits from one of the surfaces. Patent Document 5 discloses a light-emitting device that includes an LED and a light guide system. A paper entitled “Anisotropic fluorophores for liquid crystal displays” (Displays, October 1986, pp. 155-160) discloses a light guide system for displays. Here, “displays” refers to liquid crystal displays. Neither of Patent Documents 4 and 5 discloses that the guided light is converted into energy of another form by a conversion system.

Patent Document 6 discloses a window as an optical device including an anisotropic light-emitting material in a switching layer. In this optical device, the light radiated by the light-emitting material in the switching layer is guided to an optical energy conversion means by a light guide system, and is converted into thermal energy or electric energy by the optical energy conversion means. It is also disclosed that because the switching layer includes the anisotropic light-emitting material, not only absorption and emission of light can be achieved by the light-emitting material, but also transmission and non-transmission of light through the optical device can be controlled.

### PRIOR-ART DOCUMENTS

### Patent Documents

Patent Document 1: DE 3330305.

Patent Document 2: DE 3125620.

Patent Document 3: WO 2006/088369.

Patent Document 4: JP H06-318766 A.

Patent Document 5: US 2007/0273265.

Patent Document 6: JP 2011-524539 A.

### SUMMARY OF THE INVENTION

In the prior art, a polyimide alignment film is used as an alignment layer. However, polyimide has absorption in a visible light region, and is not suitable for constituting an optical device used as window glass in terms of the light resistance.

The invention aims to provide an optical device having light resistance.

The invention provides an optical device that includes: a switching layer that includes an anisotropic light-emitting material for absorbing and radiating light and switches alignment of the light-emitting material, an alignment layer in contact with the switching layer; an optical energy conversion means that converts the radiated light into at least one energy form selected from heat and electricity, and a light guide system that is in physical contact with the optical energy conversion means and guides the radiated light to the optical energy conversion means, wherein the switching layer controls transmission of light through the optical device, and the alignment layer includes 80 wt % or more of a polyorganosiloxane.

In the above configuration, since the alignment layer in the optical device includes 80 wt % or more of a polyorganosiloxane, the optical device can obtain excellent light resistance.

In addition, for the switching layer includes the light-emitting material, an additional layer for a light-emitting material is not necessary. Accordingly, the optical device has a compact configuration. In addition, manufacture of the optical device is simple and low-cost, and the manufacturing time is short. Furthermore, because the light-emitting material has anisotropy, absorptivity can be controlled without a complex mechanism.

### BRIEF DESCRIPTION OF THE DRAWINGS

FIG. 1 is a cross-sectional view of an optical device.

FIG. 2 is a schematic view of a switching layer.

FIG. 3 is a schematic view of alignments that can be adopted by a light-emitting material.

FIG. 4 illustrates a correlation between the optical density and the applied voltage.

FIG. 5 schematically illustrates an example of functions of the optical device.

FIG. 6 schematically illustrates an example of functions of the optical device.

FIG. 7 illustrates an embodiment of the optical device in a window frame.

FIG. 8 illustrates an embodiment of the optical device in a window frame.

FIG. 9 illustrates an embodiment of the optical device in a window frame.

FIG. 10 illustrates a setup for experimental purposes.

### DESCRIPTION OF THE EMBODIMENTS

Hereinafter, the invention is described in detail. An optical device of the invention includes a switching layer, an alignment layer, an optical energy conversion system as an optical energy conversion means, and a light guide system.

The switching layer is capable of switching the alignment of a light-emitting material. In one preferred embodiment, the alignment of the light-emitting material is switched using an electrical signal. In another embodiment, the alignment of the light-emitting material is switched according to the intensity of light of a specific wavelength by which the optical device is irradiated. For clarification, “switching layer” refers to a material selected from a group consisting of liquid, gel, rubber, and a combination thereof. If a liquid is used as the switching layer, a liquid crystal is preferably used. The liquid crystal may be thermotropic liquid crystal or lyotropic liquid crystal, wherein thermotropic liquid crystal is preferred. The liquid crystal is so-called a guest-host system that dissolves and aligns the light-emitting material. The liquid crystal preferably has a nematic phase at all driving temperatures. More preferably, the liquid crystal has dielectric anisotropy and hence can be aligned using an electric field. The liquid crystal is preferably rod-like liquid crystal and/or discotic liquid crystal, and may have various molecular structures such as uniaxial planar, homeotropic uniaxial, twisted nematic, splayed or cholesteric structure. If the switching layer is gel or rubber, the gel is preferably a liquid crystal gel, or the rubber is preferably a liquid crystal rubber. The gel or rubber preferably has mesogenic groups having dielectric anisotropy, and the alignment of these groups can be controlled by an electric field. In regard to both the gel and the rubber, chemical cross-linking between the mesogenic groups is low enough to provide sufficient mobility to enable switching using an electric field. In one embodiment, the gel or rubber is capable of dissolving the light-emitting material, and functions as a guest-host system for the light-emitting material. Alternatively, the light-emitting material may be chemically bonded to the liquid crystal rubber or liquid crystal gel.

The alignment layer is preferably in direct contact with an upper plate and/or a lower plate of the switching layer. The upper plate and the lower plate mean that surfaces of the switching layer are parallel to a main extension plane of the switching layer. “Direct” means that the alignment layer is in physical contact with the switching layer. “Alignment layer” preferably refers to a layer capable of inducing alignment of the light-emitting material.

The alignment layer includes 80 wt % or more of a polyorganosiloxane. Such alignment layer can be formed by using, e.g., a liquid crystal aligning agent that contains the polysiloxane and a solvent. The liquid crystal aligning agent used for forming the alignment layer preferably contains 80 wt % or more of the polyorganosiloxane in the solid content. In addition, the content of the polyorganosiloxane relative to all the polymer components in the liquid crystal aligning agent is preferably 80 wt % or more, more preferably 85 wt % or more, and even more preferably 90 wt % or more.

The liquid crystal aligning agent used in forming the alignment layer may have either a vertical alignment property or a horizontal alignment property, and can be suitably selected according to the driving method of the optical device or the type of the liquid crystals used.

The liquid crystal aligning agent having a vertical alignment property is preferably a polymer composition containing a polyorganosiloxane (A) shown below.

[Polyorganosiloxane (A)]

Regarding the polyorganosiloxane (A) contained in the polymer composition used in the invention, the weight average molecular weight (Mw) in terms of polystyrene measured by gel permeation chromatography is preferably 500 to 1,000,000, more preferably 1,000 to 100,000, and even more preferably 1,000 to 50,000.

The polyorganosiloxane (A) preferably has a group represented by formula (A-1).

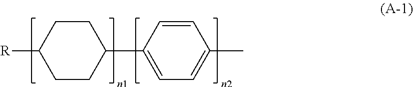

In formula (A-1), n1 is an integer of 0 to 2, and n2 is 0 or 1. When n1+n2 is 2 or greater, R is a hydrogen atom, an alkyl group having 1 to 20 carbons, or a fluoroalkyl group having 1 to 20 carbons. When n1+n2 is 0 or 1, R is a group having a steroid structure, an alkyl group having 4 to 20 carbons, or a fluoroalkyl group having 2 to 20 carbons.

Examples of R that represents the group having a steroid structure in formula (A-1) include: 3-cholestanyl group, 3-cholestenyl group, 3-lanostanyl group, 3-cholanyl group, 3-pregnal group, 3-androstanyl group, and 3-estranyl group, etc.

When the carbon number of R representing an alkyl group or a fluoroalkyl group in formula (A-1) is 3 or greater, each R is preferably a linear group. The fluoroalkyl group is preferably represented by the following formula (F):

CF₃—(CF₂)ₐ—(CH₂)_{b}— (F)

In formula (F), a and b are each an integer of 0 to 19. However, when n1+n2 in formula (A-1) is 2 or greater, a+b is an integer of 0 to 19; when n1+n2 is 0 or 1, a+b is an integer of 3 to 19.

Preferred examples of the group represented by formula (A-1) include: n-octyl, n-nonyl, n-decyl, n-undecyl, n-dodecyl, n-tridecyl, n-tetradecyl, n-pentadecyl, n-hexadecyl, n-heptadecyl, n-octadecyl, and groups represented by formulae (A-1-1) to (A-1-3), etc.

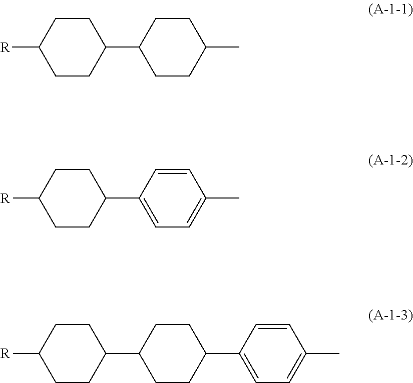

In formulae (A-1-1) to (A-1-3), each R is defined as in the case of formula (A-1).

In formulae (A-1-1) to (A-1-3), R is preferably a linear alkyl or fluoroalkyl group having 1 to 18 carbons.

The content of the group represented by formula (A-1) in the polyorganosiloxane (A) is preferably 0.0002 mol/g or more, more preferably 0.004 to 0.002 mol/g, and even more preferably 0.0005 to 0.0016 mol/g.

Such polyorganosiloxane (A) may be produced by any method as long as it includes the above features. Specifically, it can be produced by, e.g., the following methods.

1) Production Method 1 is a method in which an alkoxysilane compound, preferably a silane compound (hereafter called “silane compound (a1)”) having a group represented by formula (A-1) and an alkoxy group, or a mixture of the silane compound (a1) and another alkoxysilane compound (hereafter called “silane compound (a2)”), is reacted in the presence of a dicarboxylic acid and an alcohol.

2) Production Method 2 is a method in which the silane compound (a1) or a mixture of (a1) and the silane compound (a2) is subjected to hydrolysis and condensation.

3) Production Method 3 is a method in which a silane compound (hereafter called “silane compound (a2-1)”) having an epoxy group and an alkoxy group, or a mixture of the silane compound (a2-1) and another alkoxysilane compound (hereafter called “silane compound (a2-2)”), is reacted in the presence of a dicarboxylic acid and an alcohol and then further reacted with a compound having a group represented by formula (A-1) and a carboxyl group, which is called “specific carboxylic acid” hereafter.

4) Production Method 4 is a method in which the silane compound (a2-1) or a mixture of the silane compound (a2-1) and the silane compound (a2-2) is subjected to hydrolysis and condensation and then further reacted with the specific carboxylic acid.

Each of the silane compounds (a2-1) and (a2-2) preferably does not have a group represented by formula (A-1). Moreover, in this case, the scope of the combination of the silane compounds (a2-1) and (a2-2) matches that of the silane compound (a2).

Examples of the silane compound (a1) include those represented by formula (a1-1).

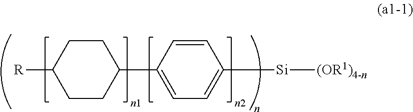

In formula (a1-1), n1, n2 and R are respectively defined as in the case of formula (A-1), n is an integer of 1 to 3, and R¹ is a phenyl group or an alkyl group having 1 to 12 carbons, or an alkylphenyl group that has an alkyl group having 1 to 12 carbons.

In formula (a1-1), n is preferably 1.

Specific examples of such silane compound (a1) include: n-butyltrimethoxysilane, n-butyltriethoxysilane, n-butyltri-n-propoxysilane, n-butyltri-i-propoxysilane, n-butyltri-n-butoxysilane, n-butyltri-sec-butoxysilane, n-butyltri-n-pentoxysilane, n-butyltri-sec-butoxysilane, n-butyltriphenoxysilane, n-butyltri-p-methylphenoxysilane, n-pentyltrimethoxysilane, n-pentyltriethoxysilane, n-pentyltri-n-propoxysilane, n-pentyltri-i-propoxysilane, n-pentyltri-n-butoxysilane, n-pentyltri-sec-butoxysilane, n-pentyltri-n-pentoxysilane, n-pentyltri-sec-butoxysilane, n-pentyltriphenoxysilane, n-pentyltri-p-methylphenoxysilane, 2-(perfluoro-n-hexyl)ethyltrimethoxysilane, 2-(perfluoro-n-hexyl)ethyltriethoxysilane, 2-(perfluoro-n-hexyl)ethyltri-n-propoxysilane, 2-(perfluoro-n-hexyl)ethyltri-i-propoxysilane, 2-(perfluoro-n-hexyl)ethyltri-n-butoxysilane, 2-(perfluoro-n-hexyl)ethyltri-sec-butoxysilane, 2-(perfluoro-n-octyl)ethyltrimethoxysilane, 2-(perfluoro-n-octyl)ethyltriethoxysilane, 2-(perfluoro-n-octyl)ethyltri-n-propoxysilane, 2-(perfluoro-n-octyl)ethyltri-i-propoxysilane, 2-(perfluoro-n-octyl)ethyltri-n-butoxysilane, 2-(perfluoro-n-octyl)ethyltri-sec-butoxysilane, n-dodecyltrimethoxysilane, n-dodecyltriethoxysilane, n-dodecyltri-n-propoxysilane, n-dodecyltri-i-propoxysilane, n-dodecyltri-n-butoxysilane, and n-dodecyltri-sec-butoxysilane, etc. One or more compounds selected from these can be used.

Examples of the silane compound (a2-1) include: 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, 3-glycidyloxypropyldimethylmethoxysilane, 3-glycidyloxypropyldimethylethoxysilane, 2-(3,4-epoxycyclohexyl)ethyltrimethoxysilane, and 2-(3,4-epoxycyclohexyl)ethyltriethoxysilane, etc. One or more compounds selected from these can be used.

The silane compound (a2-2) is preferably an alkoxysilane compound other than the silane compounds (a1) and (a2-1), and is preferably, e.g., a compound represented by formula (a2-2-1).

(R²)ₘSi(OR³)₄₋ₘ (a2-2-1)

In formula (a2-2-1), R² is an alkyl group having 1 to 3 carbons, a fluoroalkyl group having 1 to 3 carbons, or phenyl, or is an alkylphenyl group that has an alkyl group having 1 to 3 carbons, R³ is a phenyl group or an alkyl group having 1 to 12 carbons, or an alkylphenyl group that has an alkyl group having 1 to 12 carbons, and m is an integer of 0 to 3.

Specific examples of the compound represented by formula (a2-2-1) in the case where m is 0 include: tetramethoxysilane, tetraethoxysilane, tetra-n-propoxysilane, tetra-i-propoxysilane, tetra-sec-propoxysilane, tetra-n-butoxysilane, and tetra-sec-butoxysilane, etc.

In the case where m is 1, specific examples include: methyltrimethoxysilane, methyltriethoxysilane, methyltri-n-propoxysilane, methyltri-i-propoxysilane, methyltri-n-butoxysilane, methyltri-sec-butoxysilane, methyltri-n-pentoxysilane, methyltri-sec-butoxysilane, methyltriphenoxysilane, methyltri-p-methylphenoxysilane, ethyltrimethoxysilane, ethyltriethoxysilane, ethyltri-n-propoxysilane, ethyltri-i-propoxysilane, ethyltri-n-butoxysilane, ethyltri-sec-butoxysilane, ethyltri-n-pentoxysilane, ethyltri-sec-butoxysilane, ethyltriphenoxysilane, ethyltri-p-methylphenoxysilane, n-propyltrimethoxysilane, n-propyltriethoxysilane, n-propyltri-n-propoxysilane, n-propyltri-i-propoxysilane, n-propyltri-n-butoxysilane, n-propyltri-sec-butoxysilane, n-propyltri-n-pentoxysilane, n-propyltri-sec-butoxysilane, n-propyltriphenoxysilane, n-propyltri-p-methylphenoxysilane, 2-(trifluoromethyl)ethyltrimethoxysilane, 2-(trifluoromethyl)ethyltriethoxysilane, 2-(trifluoromethyl)ethyltri-n-propoxysilane, 2-(trifluoromethyl)ethyltri-i-propoxysilane, 2-(trifluoromethyl)ethyltri-n-butoxysilane, 2-(trifluoromethyl)ethyltri-sec-butoxysilane, phenyltrimethoxysilane, phenyltriethoxysilane, phenyltri-n-propoxysilane, phenyltri-i-propoxysilane, phenyltri-n-butoxysilane, and phenyltri-sec-butoxysilane, etc.

In the case where m is 2, specific examples include: dimethyldiinethoxysilane, diethyldimethoxysilane, di-n-propyldimethoxysilane, di-i-propyldimethoxysilane, dimethyldiethoxysilane, diethyldiethoxysilane, di-n-propyldiethoxysilane, di-i-propyldiethoxysilane, dimethyl-di-i-propoxysilane, diethyl-di-i-propoxysilane, di-n-propyl-di-i-propoxysilane, di-i-propyl-di-i-propoxysilane, dimethyl-di-sec-butoxysilane, diethyl-di-sec-butoxysilane, di-n-propyl-di-sec-butoxysilane, and di-i-propyl-di-sec-butoxysilane, etc.

In the case where m is 3, specific examples include: trimethylmethoxysilane, triethylmethoxysilane, tri-n-propylmethoxysilane, tri-i-propylmethoxysilane, trimethylethoxysilane, triethylethoxysilane, tri-n-propylethoxysilane, tri-i-propylethoxysilane, trimethyl-n-propoxysilane, triethyl-n-propoxysilane, tri-n-propyl-n-propoxysilane, tri-i-propyl-n-propoxysilane, trimethyl-i-propoxysilane, triethyl-i-propoxysilane, tri-n-propyl-i-propoxysilane, tri-i-propyl-i-propoxysilane, trimethyl-sec-butoxysilane, triethyl-sec-butoxysilane, tri-n-propyl-sec-butoxysilane, and tri-i-propyl-sec-butoxysilane, etc. One or more compounds selected from these can be used.

The silane compound (a2-2) is preferably one or more selected from the group consisting of ethyltrimethoxysilane, ethyltriethoxysilane, methyltrimethoxysilane, methyltriethoxysilane, tetramethoxysilane and tetraethoxysilane, and is particularly preferably one or more selected from the group consisting of tetramethoxysilane and tetraethoxysilane.

During the production of the polyorganosiloxane (A) in the invention, the proportion of each silane compound used as a raw material relative to all the silane compounds depends on the method of producing the polyorganosiloxane (A), as described below.

1) In a case where the polyorganosiloxane (A) is produced by Production Method 1 or 2:

Silane compound (a1): preferably 1 mol % or more, more preferably 2 to 40 mol %, and even more preferably 5 to 20 mol %;

Silane compound (a2): preferably 99 mol % or less, more preferably 60 to 98 mol %, and even more preferably 80 to 95 mol %.

2) In a case where the polyorganosiloxane (A) is produced by Production Method 3 or 4:

Silane compound (a2-1): preferably 50 mol % or more, more preferably 60 to 100 mol %, and even more preferably 80 to 100 mol %;

Silane compound (a2-2): preferably 50 mol % or less, more preferably 0 to 40 mol %, and even more preferably 0 to 20 mol %.

Hereinafter, a method of reacting the silane compound in the presence of a dicarboxylic acid and an alcohol in Production Methods 1 and 3 is described.

The dicarboxylic acid used during synthesis can be oxalic acid, malonic acid, a compound obtained by bonding two carboxyl groups to an alkylene group having 2 to 4 carbons, and benzenecarboxylic acid, etc. Specific examples include: oxalic acid, malonic acid, succinic acid, glutaric acid, adipic acid, phthalic acid, isophthalic acid, and terephthalic acid, etc. One or more selected from these are preferably used. Oxalic acid is particularly preferably used.

The dicarboxylic acid is used in a proportion such that the amount of carboxyl groups becomes preferably 0.2 to 2.0 mol, and more preferably 0.5 to 1.5 mol, relative to a total of 1 mol of alkoxy groups in the silane compound used as a raw material.

A primary alcohol can be suitably used as the alcohol. Specific examples thereof include: methanol, ethanol, n-propanol, i-propanol, n-butanol, i-butanol, sec-butanol, t-butanol, n-pentanol, i-pentanol, 2-methylbutanol, t-pentanol, 3-methoxybutanol, n-hexanol, 2-methylpentanol, 2-ethylbutanol, heptanol-3, n-octanol, 2-ethylhexanol, n-nonyl alcohol, 2,6-dimethyl heptanol-4, n-decanol, phenol, cyclohexanol, methylcyclohexanol, 3,3,5-trimethylcyclohexanol, benzyl alcohol, and diacetone alcohol, etc. One or more selected from these compounds are preferably used. The alcohol used herein is preferably an aliphatic primary alcohol having 1 to 4 carbons, more preferably one or more selected from the group consisting of methanol, ethanol, i-propanol, n-propanol, i-butanol, sec-butanol and t-butanol, and particularly preferably one or more compounds selected from methanol and ethanol.

In Production Methods 1 and 3, the alcohol is used in a proportion such that the proportion of the silane compound and the dicarboxylic acid becomes preferably 3 to 80 wt %, and more preferably 25 to 70 wt %, relative to the total amount of the reaction solution.

The reaction temperature is preferably 1 to 100° C., and more preferably 15 to 80° C. The reaction time is preferably 0.5 to 24 hours, and more preferably 1 to 8 hours. In addition, in the reaction of the silane compound in Production Methods 1 and 3, it is preferred to not use a solvent other than the alcohol as described above.

Moreover, in the production methods as described above, it is inferred that the polyorganosiloxane being a (co-)condensate of the silane compound is generated by causing the alcohol to act on an intermediate generated by the reaction between the silane compound and the dicarboxylic acid.

Next, the hydrolysis and condensation reactions of the silane compound carried out in Production Methods 2 and 4 are described. The hydrolysis and condensation reactions can be carried out by reacting the silane compound and water preferably in a suitable organic solvent and preferably in the presence of a catalyst.

The amount of the water used herein is preferably 0.5 to 2.5 mol relative to a total of 1 mol of alkoxy groups in the silane compound used as a raw material.

Examples of the catalyst include acids, bases, and metal compounds, etc. Specific examples of acids as the catalyst include: hydrochloric acid, sulfuric acid, nitric acid, acetic acid, formic acid, oxalic acid, and maleic acid, etc.

The bases can be inorganic bases or organic bases. Examples of inorganic bases include: ammonia, sodium hydroxide, potassium hydroxide, sodium methoxide, potassium methoxide, sodium ethoxide, and potassium ethoxide, etc.

Examples of the organic bases include: tertiary organic amines, such as triethylamine, tri-n-propylamine, tri-n-butylamine, pyridine and 4-dimethylaminopyridine; and tetramethylammonium hydroxide, etc. Examples of the metal compounds include titanium compounds, and zirconium compounds, etc.

The proportion of the catalyst used is preferably 10 weight parts or less, more preferably 0.001 to 10 weight parts, and even more preferably 0.001 to 1 weight part, relative to a total of 100 weight parts of the silane compound used as a raw material.

Examples of the organic solvent include: alcohols, ketones, amides, esters and other aprotic compounds. The alcohol can be any one of an alcohol having one hydroxyl group, an alcohol having a plurality of hydroxyl groups, and a partial ester of an alcohol having a plurality of hydroxyl groups. The ketone is preferably a monoketone or a β-diketone.

Specific examples of the organic solvent that is an alcohol having one hydroxyl group include: methanol, ethanol, n-propanol, i-propanol, n-butanol, i-butanol, sec-butanol, t-butanol, n-pentanol, i-pentanol, 2-methylbutanol, t-pentanol, 3-methoxybutanol, n-hexanol, 2-methylpentanol, 2-ethylbutanol, heptanol-3, n-octanol, 2-ethylhexanol, n-nonyl alcohol, 2,6-dimethyl heptanol-4, n-decanol, phenol, cyclohexanol, methylcyclohexanol, 3,3,5-trimethylcyclohexanol, benzyl alcohol, and diacetone alcohol, etc.

Specific examples of the alcohol having a plurality of hydroxyl groups include: ethylene glycol, 1,2-propylene glycol, 1,3-butylene glycol, pentanediol-2,4,2-methyl pentanediol-2,4, hexanediol-2,5, heptanediol-2,4,2-ethyl hexanediol-1,3, diethylene glycol, dipropylene glycol, triethylene glycol, and tripropylene glycol, etc.

Examples of the partial ester of an alcohol having a plurality of hydroxyl groups include: ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether, etc.

Examples of the monoketones include acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethyl nonanone, cyclohexanone, 2-hexanone, methyl cyclohexanone, 2,4-pentanedione, acetonyl acetone, acetophenone, and fenchone, etc.

Examples of the β-diketones include: acetylacetone, 2,4-hexanedione, 2,4-heptanedione, 3,5-heptanedione, 2,4-octanedione, 3,5-octanedione, 2,4-nonanedione, 3,5-nonanedione, 5-methyl-2,4-hexanedione, 2,2,6,6-tetramethyl-3,5-heptanedione, and 1,1,1,5,5,5-hexafluoro-2,4-pentanedione, etc.

Examples of the amides include: formamide, N-methylformamide, N,N-dimethylformamide, N-ethylformamide, N,N-diethylformamide, acetamide, N-methylacetamide, N,N-dimethylacetamide, N-ethylacetamide, N,N-diethylacetamide, N-methylpropionamide, N-methylpyrrolidin, N-formylmorpholine, N-formylpiperidine, N-formylpyrrolidine, N-acetylmorpholine, N-acetylpiperidine, and N-acetylpyrrolidine, etc.

Examples of the esters include: diethyl carbonate, ethylene carbonate, propylene carbonate, diethyl carbonate, methyl acetate, ethyl acetate, y-butyrolactone, y-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate, etc.

Examples of the other aprotic solvents include: acetonitrile, dimethyl sulfoxide, N,N,N′,N′-tetraethyl sulfamide, hexamethyl phosphoric triamide, N-methyl morpholone, N-methylpyrrole, N-ethylpyrrole, N-methyl-Δ3-pyrroline, N-methylpiperidine, N-ethylpiperidine, N,N-dimethylpiperazine, N-methylimidazole, N-methyl-4-piperidone, N-methyl-2-piperidone, N-methyl-2-pyrrolidone, 1,3-dimethyl-2-imidazolidinone, and 1,3-dimethyltetrahydro-2(1H)-pyrimidinone, etc. One or more selected from these compounds can be used.

The organic solvent is used in a proportion such that the proportion of the total weight of components other than the organic solvent in the reaction solution to the total weight of the reaction solution becomes preferably 1 to 90 wt %, and more preferably 10 to 70 wt %. The water added during the hydrolysis and condensation reactions of the silane compound can be intermittently or continuously added in the silane compound as a raw material or in a solution obtained by dissolving the silane compound in the organic solvent.

The catalyst may be added in advance in the silane compound as a raw material or in the solution obtained by dissolving the silane compound in the organic solvent, or may be dissolved or dispersed in the added water. The reaction temperature is preferably 1 to 100° C., and more preferably 15 to 80° C. The reaction time is preferably 0.5 to 24 hours, and more preferably 1 to 8 hours.

With the above means, the polyorganosiloxane (A) contained in the liquid crystal aligning agent is directly obtained in Production Methods 1 and 2. On the other hand, in Production Methods 3 and 4, the polyorganosiloxane having an epoxy group that is a precursor of the polyorganosiloxane (A) is obtained. In Production Methods 3 and 4, by further reacting the polyorganosiloxane having an epoxy group with the specific carboxylic acid, the polyorganosiloxane (A) contained in the liquid crystal aligning agent can be obtained.

The specific carboxylic acid used in the reaction with the polyorganosiloxane having an epoxy group is a compound having the group represented by formula (A-1) and a carboxyl group. Examples thereof include a compound represented by formula (C-1).

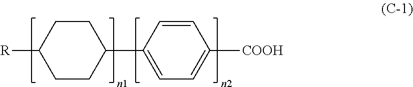

In formula (C-1), n1, n2 and R are respectively defined as in the case of formula (A-1).

Specific examples of the compound represented by formula (C-1) include: valeric acid, caproic acid, caprylic acid, decanoic acid, dodecanoic acid, tetradecanoic acid, 4-(n-pentyl)benzoic acid, 4-(n-hexyl)benzoic acid, 4-(n-heptyl)benzoic acid, 4-(n-octyl)benzoic acid, 4-(n-nonyl)benzoic acid, 4-(n-decyl)benzoic acid, 4-(n-dodecyl)benzoic acid, 4-(n-octadecyl)benzoic acid, 4-(4-pentyl-cyclohexyl)-benzoic acid, and 4-(4-heptyl-cyclohexyl)-benzoic acid, etc. One or more selected from these compounds can be used.

The proportion of the specific carboxylic acid used in the reaction with the polyorganosiloxane having an epoxy group is preferably 0.05 to 0.9 mol, more preferably 0.1 to 0.7 mol, and even more preferably 0.2 to 0.5 mol, relative to 1 mol of the epoxy group in the precursor of the (A) polyorganosiloxane.

The reaction between the polyorganosiloxane having an epoxy group and the specific carboxylic acid can be carried out in the presence of a suitable catalyst preferably in a suitable organic solvent. The catalyst used herein can be an organic base, or can be a well-known compound as a so-called curing accelerator for accelerating the reaction between an epoxy compound and a carboxylic acid.

Examples of the organic base include: primary to secondary organic amines, such as ethylamine, diethylamine, piperazine, piperidine, pyrrolidine, and pyrrole; tertiary organic amines, such as triethylamine, tri-n-propylamine, tri-n-butylamine, pyridine, 4-dimethylaminopyridine, and diazabicycloundecene; and quaternary organic amines, such as tetramethylammonium hydroxide. Among these organic bases, the tertiary organic amines such as triethylamine, tri-n-propylamine, tri-n-butylamine, pyridine and 4-dimethylaminopyridine, and the quaternary organic amines such as tetramethylammonium hydroxide, are preferred, and one or more selected from these compounds can be used.

Examples of the curing accelerator include: tertiary amines, such as benzyldimethylamine, 2,4,6-tris(dimethylaminomethyl)phenol, cyclohexyldimethylamine, and triethanolamine; imidazole compounds, such as 2-methylimidazole, 2-n-heptylimidazole, 2-n-undecylimidazole, 2-phenylimidazole, 2-phenyl-4-methylimidazole, 1-benzyl-2-methylimidazole, 1-benzyl-2-phenylimidazole, 1,2-dimethylimidazole, 2-ethyl-4-methylimidazole, 1-(2-cyanoethyl)-2-methylimidazole, 1-(2-cyanoethyl)-2-n-undecylimidazole, 1-(2-cyanoethyl)-2-phenylimidazole, 1-(2-cyanoethyl)-2-ethyl-4-methylimidazole, 2-phenyl-4-methyl-5-hydroxymethylimidazole, 2-phenyl-4,5-di(hydroxymethyl)imidazole, 1-(2-cyanoethyl)-2-phenyl-4,5-di[(2′-cyanoethoxy)methyl]imidazole, 1-(2-cyanoethyl)-2-n-undecylimidazolium trimellitate, 1-(2-cyanoethyl)-2-phenylimidazolium trimellitate, 1-(2-cyanoethyl)-2-ethyl-4-methylimidazolium trimellitate, 2,4-diamino-6-[2′-methylimidazolyl-(1′)]ethyl-s-triazine, 2,4-diamino-6-(2′-n-undecylimidazolyl)ethyl-s-triazine, 2,4-diamino-6-[2′-ethyl-4′-methylimidazolyl-(1′)]ethyl-s-triazine, isocyanuric acid adduct of 2-methylimidazole, isocyanuric acid adduct of 2-phenylimidazole, and isocyanuric acid adduct of 2,4-diamino-6-[2′-methylimidazolyl-(1′)]ethyl-s-triazine; organic phosphorus compounds, such as diphenyl phosphine, triphenyl phosphine, and triphenyl phosphite;

quaternary phosphonium salts, such as benzyltriphenylphosphonium chloride, tetra-n-butylphosphonium bromide, methyltriphenylphosphonium bromide, ethyltriphenylphosphonium bromide, n-butyltriphenylphosphonium bromide, tetraphenylphosphonium bromide, ethyltriphenylphosphonium iodide, ethyltriphenylphosphonium acetate, tetra-n-butylphosphonium o,o-diethylphosphorodithionate, tetra-n-butylphosphonium benzotriazolate, tetra-n-butylphosphonium tetrafluoroborate, tetra-n-butylphosphonium tetraphenylborate, and tetraphenylphosphonium tetraphenylborate; diazabicycloalkenes, such as 1,8-diazabicyclo[5.4.0]undecene-7 and organic acid salts thereof; organic metal compounds, such as zinc octylate, tin octylate, and aluminum acetylacetone complex; quaternary ammonium salts, such as tetraethylammonium bromide, tetra-n-butylammonium bromide, tetraethylammonium chloride, and tetra-n-butylammonium chloride; boron compounds, such as boron trifluoride and triphenyl borate; metal halogen compounds, such as zinc chloride and stannic chloride; and latent curing accelerators, including: high-melting point dispersible latent curing accelerators, such as amine adduct type accelerators including dicyandiamide and an adduct of an amine with epoxy resin; microcapsule type latent curing accelerators obtained by coating surfaces of the curing accelerators such as the above imidazole compounds, organic phosphorus compounds and quaternary phosphonium salts with a polymer; amine salt type latent curing accelerators; and high-temperature dissociation type thermally cationic polymerization latent curing accelerators, such as Lewis acid salts and Brønsted acid salts.

Among them, the quaternary ammonium salts such as tetraethylammonium bromide, tetra-n-butylammonium bromide, tetraethylammonium chloride and tetra-n-butylammonium chloride are preferred.

The catalyst is used in a proportion of preferably 100 weight parts or less, more preferably 0.01 to 100 weight parts, and even more preferably 0.1 to 20 weight parts, relative to 100 weight parts of the polyorganosiloxane having an epoxy group.

Examples of the organic solvent used in the reaction between the polyorganosiloxane having an epoxy group and the specific carboxylic acid include: hydrocarbon compounds, ether compounds, ester compounds, ketone compounds, amide compounds, and alcohol compounds, etc. Among them, ether compounds, ester compounds and ketone compounds are preferred in view of the solubility of the raw materials and the product and easiness of the purification of the product. The solvent is used in an amount such that the solid content concentration (the proportion of the total weight of components other than the solvent in the reaction solution relative to the total weight of the solution) becomes preferably 0.1 wt % or more, and more preferably 5 to 50 wt %.

The reaction temperature is preferably 0 to 200° C., and more preferably 50 to 150° C. The reaction time is preferably 0.1 to 50 hours, and more preferably 0.5 to 20 hours.

The polyorganosiloxane (A) obtained by any of Production Methods 1 to 4 as described above is preferably purified by a well-known suitable method and then provided for adjustment of the polymer composition.

The liquid crystal aligning agent having a horizontal alignment property is preferably a polymer composition containing, among the polyorganosiloxane (A), a polyorganosiloxane that contains zero or a reduced amount of the group represented by formula (A-1). Such polyorganosiloxane can be produced by, e.g., a method of reacting the silane compound (a2) in the presence of a dicarboxylic acid and an alcohol, a method of subjecting the silane compound (a2) to hydrolysis and condensation, a method of reacting the silane compound (a2-1) or a mixture of the silane compound (a2-1) and the silane compound (a2-2) in the presence of a dicarboxylic acid and an alcohol, and a method of subjecting a mixture of the silane compound (a2-1) and the silane compound (a2-2) to hydrolysis and condensation, etc. The description of the production of the polyorganosiloxane (A) is applicable to the reaction conditions in each production method.

[Other Components]

The liquid crystal aligning agent as the polymer composition contains the above polyorganosiloxane as an essential component, and may further contain other components as long as the effect of the invention is not impaired. The other components that can be used include, e.g., polymers (hereinafter “other polymers”) other than polyorganosiloxane, and an epoxy compound, etc.

The other polymers can be used to further improve solution properties of the obtained polymer composition, electrical properties of a formed coating film and the response rate of a resulting LCD device. Examples of the other polymers include polyamic acid, polyimide, polyamic acid ester, polyester, polyamide, polysiloxane, cellulose derivative, polyacetal, polystyrene derivative, poly(styrene-phenylmaleimide) derivative, and poly(meth)acrylate, etc. One or more selected from these compounds can be used. Among them, at least one selected from the group consisting of polyamic acid and polyimide is preferred.

The polyamic acid can be produced by, e.g., reacting the tetracarboxylic dianhydride and a diamine described in JP-A-2010-097188 by a well-known method.

An aliphatic tetracarboxylic dianhydride is preferably used as the tetracarboxylic dianhydride for synthesizing the polyamic acid. Specific examples thereof include: 1,2,3,4-cyclobutanetetracarboxylic dianhydride, 2,3,5-tricarboxycyclopentylacetic dianhydride, 1,3,3a,4,5,9b-hexahydro-5-(tetrahydro-2,5-dioxo-3-furanyl)-naphtho[1,2-c]-furan-1,3-dione, 1,3,3a,4,5,9b-hexahydro-8-methyl-5-(tetrahydro-2,5-dioxo-3-furanyl)-naphtho[1,2-c]-furan-1,3-dione, 3-oxabicyclo[3.2.1]octane-2,4-dione-6-spiro-3′-(tetrahydrofuran-2′,5′-dione), 5-(2,5-dioxotetrahydro-3-furanyl)-3-methyl-3-cyclohexene-1,2-dicarboxylicanhydride, 3,5,6-tricarboxy-2-carboxymethylnorbornane-2:3,5:6-dianhydride, 2,4,6,8-tetracarboxybicyclo[3.3.0]octane-2:4,6:8-dianhydride 4,9-dioxatricyclo[5.3.1.0^{2,6}]undecane-3,5,8,10-tetraone, and bicyclo[2.2.1]heptane-2,3,5,6-tetracarboxylic dianhydride, etc.

The diamine used for synthesizing the polyamic acid is preferably a diamine having a group having a property of aligning liquid crystal molecules, hereinafter called a “liquid crystal aligning diamine”, and more preferably a mixture of the liquid crystal aligning diamine and other diamine(s).

Examples of the liquid crystal aligning diamine include: cholestanyloxy-3,5-diaminobenzene, cholestenyloxy-3,5-diaminobenzene, cholestanyloxy-2,4-diaminobenzene, cholestenyloxy-2,4-diaminobenzene, cholestanyl 3,5-diaminobenzoate, cholestenyl 3,5-diaminobenzoate, lanostanyl 3,5-diaminobenzoate, 3,6-bis(4-aminobenzoyloxy)cholestane, 3,6-bis(4-aminophenoxy)cholestane, dodecanoxy-2,4-diaminobenzene, tetradecanoxy-2,4-diaminobenzene, pentadecanoxy-2,4-diaminobenzene, hexadecanoxy-2,4-diaminobenzene, octadecanoxy-2,4-diaminobenzene, dodecanoxy-2,5-diaminobenzene, tetradecanoxy-2,5-diaminobenzene, pentadecanoxy-2,5-diaminobenzene, hexadecanoxy-2,5-diaminobenzene, octadecanoxy-2,5-diaminobenzene, and compounds represented by the formulae below.

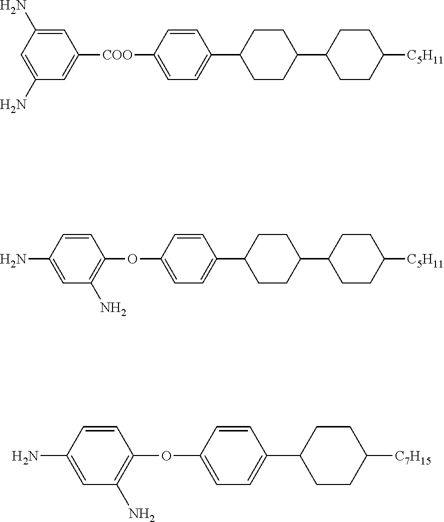

One or more selected from these compounds can be used.

Examples of the other diamines include: p-phenylenediamine, 3,5-diaminobenzoic acid, 4,4′-diaminodiphenyl ether, 4,4′-diaminodiphenylmethane, 2,2′-dimethyl-4,4′-diaminobiphenyl, 4,4′-diamino-2,2′-bis(trifluoromethyl)biphenyl, 4,4′-diaminodiphenylamine, and 4,4′-(m-phenylenediisopropylidene)dianiline, etc. One or more selected from these compounds can be used.

In the diamines used for synthesizing the polyamic acid, the content of the liquid crystal aligning diamine is preferably 3 mol % or more, more preferably 4 to 80 mol %, even more preferably 5 to 50 mol % and particularly preferably 10 to 40 mol %, relative to all the diamines.

The tetracarboxylic dianhydride and the diamine for the synthesis reaction of the polyamic acid are used in a proportion such that the amount of anhydride groups in the tetracarboxylic dianhydride becomes preferably 0.2 to 2 equivalents, more preferably 0.3 to 1.2 equivalents, per equivalent of the amino groups in the diamine.

The synthesis reaction of the polyamic acid is preferably carried out in an organic solvent at preferably −20 to 150° C. and more preferably 0 to 100° C. for preferably 0.1 to 24 hours and more preferably 0.5 to 12 hours. Examples of the organic solvent used for the reaction include: aprotic polar solvents, phenol and derivatives thereof, alcohols, ketones, esters, ethers, halogenated hydrocarbons, and hydrocarbons, etc.

The polyimide can be produced by subjecting the polyamic acid produced as above to dehydration and ring-closure to imidize the same. The dehydration and ring-closure of the polyamic acid is carried out preferably by a method of heating the polyamic acid, or a method of dissolving the polyamic acid in an organic solvent and adding to this solution a dehydrating agent and a catalyst for dehydration and ring-closure, and heating if necessary. The latter method is preferred.

In the method of adding a dehydrating agent and a catalyst for dehydration and ring-closure to the polyamic acid solution, examples of the dehydrating agent include anhydrides such as acetic anhydride, propionic anhydride, and trifluoroacetic anhydride, etc. The amount of the dehydrating agent used is preferably 0.01 to 20 mol relative to 1 mol of amic acid structures in the polyamic acid. Examples of the catalyst for dehydration and ring-closure include tertiary amines such as pyridine, collidine, lutidine, and triethylamine, etc. The amount of the catalyst for dehydration and ring-closure used is preferably 0.01 to 10 mol relative to 1 mol of the dehydrating agent used. Examples of the organic solvent for the dehydration and ring-closure reaction include the organic solvents exemplified above for synthesis of the polyamic acid. The reaction temperature of the dehydration and ring-closure reaction is preferably 0 to 180° C., and more preferably 10 to 150° C. The reaction time is preferably 1.0 to 120 hours, and more preferably 2.0 to 30 hours.

If the polymer composition contains the other polymers, the proportion of the other polymers used is preferably less than 20 wt %, more preferably less than 15 wt %, and even more preferably less than 10 wt %, relative to the total amount of polymers in the polymer composition.

The polymer composition may contain the epoxy compound in order to further improve the adhesiveness of the formed coating film to the substrate, the heat resistance of the formed coating film, or the response speed of the resulting LCD device.

Such epoxy compound is preferably an epoxy compound having two or more epoxy groups in one molecule, and preferred examples thereof include: ethylene glycol diglycidyl ether, polyethylene glycol diglycidyl ether, propylene glycol diglycidyl ether, tripropylene glycol diglycidyl ether, polypropylene glycol diglycidyl ether, neopentyl glycol diglycidyl ether, 1,6-hexanediol diglycidyl ether, glycerin diglycidyl ether, trimethylolpropane triglycidyl ether, 2,2-dibromoneopentyl glycol diglycidyl ether, N,N,N′,N′-tetraglycidyl-m-xylene diamine, 1,3-bis(N,N-diglycidylaminomethyl)cyclohexane, N,N,N′,N′-tetraglycidyl-4,4′-diaminodiphenylmethane, N,N-diglycidyl-benzylamine, N,N-diglycidyl-aminomethylcyclohexane, and N,N-diglycidyl-cyclohexylamine, etc. Epoxy compounds having two or more N-glycidyl groups in one molecule are particularly preferred.

The content of the epoxy compound in the polymer composition in the invention is preferably 50 weight parts or less, more preferably 1 to 40 weight parts, and even more preferably 5 to 30 weight parts, relative to a total of 100 weight parts of polymers.

Examples of the other components include, in addition to the above compounds, a photopolymerization initiator, a radical scavenger, and a photostabilizer, etc.

[Polymer Composition]

The polymer composition (liquid crystal aligning agent) used in formation of the liquid crystal layer is preferably prepared as a solution in which the above polyorganosiloxane and an optional other component are dissolved in a suitable organic solvent.

Examples of the organic solvent that can be used herein include: N-methyl-2-pyrrolidone, y-butyrolactone, y-butyrolactam, N,N-dimethylformamide, N,N-dimethylacetamide, 4-hydroxy-4-methyl-2-pentanone, ethylene glycol monomethyl ether, butyl lactate, butyl acetate, methyl methoxypropionate, ethyl ethoxypropionate, ethylene glycol methyl ether, ethylene glycol ethyl ether, ethylene glycol-n-propyl ether, ethylene glycol-i-propyl ether, ethylene glycol-n-butyl ether (i.e., butyl cellosolve), ethylene glycol dimethyl ether, ethylene glycol ethyl ether acetate, diethylene glycol dimethyl ether, diethylene glycol diethyl ether, diethylene glycol monomethyl ether, diethylene glycol monoethyl ether, diethylene glycol monomethyl ether acetate, diethylene glycol monoethyl ether acetate, diisobutyl ketone, isoamyl propionate, isoamyl isobutyrate, and diisopentyl ether, etc.

The organic solvent is used in a proportion such that the solid content concentration of the polymer composition (the ratio of the total weight of components other than the organic solvent in the polymer composition to the total weight of the polymer composition) becomes preferably 1 to 15 wt %, and more preferably 1.5 to 8 wt %.

The alignment layer formed using the polymer composition is a double layer that contains on an electrode a polymer layer or a single photosensitive command surface. The polymer layer can be a buffed, rubbed, or non-buffed or non-rubbed polymer layer. When the alignment layer is a double layer on an electrode, the polymer layer is a thin layer having a thickness of 20 to 400 nm, more preferably 30 to 300 nm and most preferably 50 to 200 nm. More preferably, the double layer having the polymer layer formed on the electrode is used as the alignment layer and stacked such that the polymer layer in the double-layer structure is located closest to the switching layer. In a preferred embodiment, the electrode has transmissivity. Preferably, two electrodes can be disposed on either an upper surface or a lower surface of the switching layer, or disposed as in-plane patterned electrodes on one side of the switching layer, wherein a voltage can be applied to the optical device by means of the electrodes.

When the alignment layer is a photosensitive command surface, the alignment of the light-emitting material is controlled by the intensity of light of a specific wavelength by which a command surface of the optical device is irradiated. Preferably, the command surface is controlled by light irradiation having a wavelength of 200 to 1000 nm, more preferably 300 to 450 nm. The photosensitive command surface is a thin layer and may be a self-assembled monolayer having a thickness of up to 50 nm, more preferably up to 150 nm and most preferably up to 200 nm. The photosensitive command surface in the alignment layer preferably uses a photochromic compound that may be azobenzene, stilbene, cinnamate, α-hydrazono-β-ketoester, spiropyran, benzylidenephthalimidene or α-benzylideneacetophenone.

The switching layer contains an anisotropic light-emitting material. The anisotropic light-emitting material refers to a substance of which the absorption characteristics and emission characteristics of light depend on the propagation direction, the wavelength and/or the polarization direction of the incident light. The light-emitting material is capable of absorbing light in a specific wavelength range of the light spectrum, preferably of the visible spectrum. Most of the absorbed photon energy is re-radiated as photons of a longer wavelength. The propagation directions of the absorbed photons and the radiated photons have no direct connection with each other. Moreover, the light-emitting material refers to a light-emitting dye or a light-emitting quantum dot. A quantum dot refers to a semiconductor particle whose excitons are confined in all three spatial directions. Accordingly, light can be absorbed over a predetermined wavelength range, and the absorbed energy can be radiated as photons over a smaller wavelength range.

The light-emitting material itself may constitute the switching layer. That is, the alignment of the light-emitting material may be directly switched by application of an external electric field. In another case, the light-emitting material (guest) is supported by an isotropically aligned host such as an anisotropic liquid, rubber or gel. In this preferred embodiment, the light-emitting material has dielectric anisotropy and is directly switched by an applied voltage. In the latter case, a switchable host, e.g., a liquid crystal in the switching layer, is no longer required.

The switching layer may contain a chirality induction agent (chiral doping agent). In this case, a desired twist is preferably achieved over the entire thickness of the cell. For example, the director preferably rotates at least 270° over the entire thickness of the cell. Examples of the chirality induction agent include CB15, S-811 and IS-4651, etc., all of which are produced by Merck. The content of the chirality induction agent is preferably 2 to 10 wt %, relative to the sum of the liquid crystal and the light-emitting material used for forming the switching layer.

The optical device includes an energy conversion system, and a light guide system is in physical contact with the energy conversion system. An optical contact between the energy conversion system, an intermediate layer and the light guide system means that there is a physical contact. The intermediate layer is preferably sandwiched between the light guide system and the energy conversion system. That is, by this physical contact, the light guide system physically touches the intermediate layer, and the energy conversion system physically touches the intermediate layer. Furthermore, since the light guide system and the energy conversion system can be separated from each other by a distance much shorter than a light wavelength by interposing any intermediate layer capable of separating the light guide system and the energy conversion system, interference fringes are not formed. The intermediate layer is preferably a very thin light transmissive adhesive layer, e.g., Norland Optical Adhesive 71 (produced by Norland Products Inc.). The energy conversion system converts light into at least one energy form selected from heat and electricity. Due to the contact between the light guide system and the energy conversion system, a mechanism for focusing the radiated light on the energy conversion system is not required. Accordingly, the optical device is highly reliable and robust.

The energy conversion system is preferably at least one photovoltaic cell and/or at least one photo-thermal converter. The energy conversion system is preferably an array of photovoltaic cells. Any type of photovoltaic cell that absorbs the wavelength of the guided light can be used as the photovoltaic cell. For example, the photovoltaic cell may be a silicon wafer-based cell using monocrystalline silicon, polycrystalline silicon or amorphous silicon. Alternatively, the photovoltaic cell may be a thin-film photovoltaic cell, such as a GaAs cell, a microcrystalline silicon or cadmium telluride cell. In addition, a photovoltaic cell composed of organic compounds (polymer-based photovoltaics) using organic semiconductors or carbon nanotubes, or photovoltaics including quantum dots can also be used.

The anisotropic light-emitting material preferably exhibits dichroism. Dichroism means that the light-emitting material has strong absorption along a first axis of the light-emitting material. The first axis is expressed as the absorption axis of a molecule or as the absorption axis of the light-emitting material. The light-emitting material has low absorption in axes other than the absorption axis. In a preferred embodiment, the light-emitting material exhibits high absorption for polarized light of which the electric field vector is parallel to the absorption axis of the light-emitting material, and exhibits low absorption for polarized light of which the electric field vector is perpendicular to the absorption axis of the light-emitting material. The absorption axis of the light-emitting material may be the long axis or any other axis of the light-emitting material. The light-emitting material is preferably a dye and is preferably fluorescent and/or phosphorescent. Furthermore, the light-emitting material may alternatively be a composite including two or more different light-emitting materials.

In one preferred embodiment, the light-emitting material is a fluorescent dye. Fluorescence is a special kind of luminescence, and occurs when the energy supplied by the electromagnetic irradiation causes conversion of an electron of an atom from a low energy state into an “excited” high energy state. Then, when the electron falls to the low energy state, this additional energy is released in the form of light (luminescence) of a longer wavelength.

The light guide system preferably guides the radiated light by total internal reflection. Total internal reflection occurs when a ray of light enters a boundary of the intermediate layer at an angle greater than the critical angle with respect to the surface normal. If the refractive index is lower at one side of the boundary than at the other side, no light can pass through, and all of the light is very effectively reflected. The critical angle is an incidence angle greater than the angle at which the total internal reflection occurs. Preferably, 100% of the incident light is guided into the light guide system.

Preferably, the light guide system includes at least a first intermediate layer as a central part of the light guide system and a second intermediate layer as a boundary part of the light guide system. The refractive index of the first intermediate layer is preferably equal to or higher than that of the second intermediate layer. In addition, the first intermediate layer includes the light-emitting material. Hence, the light radiated from the light-emitting material is reflected at the boundary surface between the two intermediate layers and is reflected to the first intermediate layer due to the higher refractive index. In a preferred embodiment, since the reflection at the boundary is total reflection, the radiated light is guided into the light guide system by the total internal reflection. Advantageously, no light intensity is lost during the light guiding process. An example of the light guide system is a solar concentrator and/or an optical fiber. In one preferred embodiment, the light guide system includes a glass sheet, an alignment layer, a switching layer containing an anisotropic light-emitting material, another alignment layer, and another glass sheet. In the air, the light radiated in the switching layer is mainly reflected at the interface between the glass and the air, and returns into the light guide system. The radiated light can be more reliably guided inside the light guide system by “normal” reflection. “Normal reflection” means that the incidence angle is not equal to the critical angle used for the total reflection. The light guide system is also referred to as a wave guiding system in the invention.

The switching layer is preferably attached to a supporting means on at least one side thereof. In a preferred embodiment, the switching layer is sandwiched between the supporting means. In a preferred embodiment, the optical device is a window, and in that case, the supporting means is a glass plate and/or a polymer plate. The invention is not limited to flat planes but includes layers that have been bent, molded or otherwise shaped. Materials suitable for the plates have very high transmissivity with respect to the radiated light conveyed through the wave guiding system. Examples of the suitable materials include transparent polymers, glass, transparent ceramics and combinations thereof. The glass may be silica-based inorganic glass. The polymers may be (semi-)crystalline or amorphous, and suitable examples thereof include: polymethyl methacrylate, polystyrene, polycarbonate, cyclic olefin copolymer, polyethylene terephthalate, polyethersulfone, cross-linked acrylate, epoxy, urethane, silicone rubber, combinations thereof and copolymers thereof. In a preferred embodiment, the glass is silica-based float glass. The switching layer and the light-emitting material are sandwiched between at least two planes (glass or polymer plates). The switching layer is protected from mechanical stress and contamination by the planes, thus supporting the light-emitting material and extending its life. In another embodiment of the invention, the sheet glass is dyed or an extra dyed layer is disposed between the sheet glass and the light-emitting material. The dyed sheet glass or the extra dyed layer protects the light-emitting material from UVA irradiation and/or UVB irradiation and/or specific wavelengths detrimental to the light-emitting material.

Preferably, the supporting means is a shaped panel, and the energy conversion system is arranged on at least one side of the supporting means and perpendicular to a main extension plane of the supporting means. Therefore, the position of the energy conversion system is inconspicuous. If the optical device is a window, the energy conversion system is preferably arranged in the window frame and is thus invisible to an observer.

The optical device preferably exhibits light absorptivity and/or light transmissivity. More preferably, the ratio between absorbed light and transmitted light depends on the applied voltage. For example, after a predetermined voltage is applied, the optical device mainly exhibits transmissivity with respect to light, and after a different voltage is applied, the optical device mainly exhibits opacity. To change the properties of the optical device, different voltages or different kinds of voltage profiles, e.g., sawtooth voltage, square-wave voltage or trapezoidal voltage, are used. Furthermore, characteristics of the optical device can also vary depending on different amplitudes, wavelengths or frequencies.

To realize the opacity and transmissivity, the alignment of the light-emitting material in the switching layer is preferably variable with respect to the main extension plane of the switching layer. Since the light-emitting material has anisotropy, the absorptivity of the light-emitting material varies with the alignment of the light-emitting material with respect to the incident light. To enable the optical device to exhibit mainly transmissivity, for example, the absorption axis of the light-emitting material is arranged perpendicular to the main extension plane of the switching layer. Accordingly, the absorption axis of the light-emitting material is perpendicular to the polarization direction of the electric field vector of the incident light, and less light is absorbed by the light-emitting material. In this case, most of the light passes the optical device. That is, the optical device has high transmissivity and low absorptivity. In this case, the light-emitting material is at least aligned in a transmitting state. Conversely, the light-emitting material can alternatively be aligned such that less light can pass it. To further improve the absorptivity of the optical device, the absorption axis of the light-emitting material is preferably aligned parallel to the main extension plane of the switching layer and parallel to the polarization direction of the electric field vector of the incident light. Hence, more light is absorbed, radiated and guided to the energy conversion means, and the energy conversion efficiency is higher than in the transmitting state. In this case, the light-emitting material is at least aligned in an absorbing state. The absorbed light is preferably sunlight, wherein all polarization directions are preferably in equipartition. The absorption band of the light-emitting material covers a part of the spectrum of sunlight. To classify the opacity and transmissivity of the optical device, the optical density can be used. The optical density is a unitless measure of the transmittance of an optical element with respect to a predetermined length and a predetermined wavelength λ, and is calculated according to the following formula. Thus, the higher the optical density, namely the higher the opacity, the lower the transmittance.

$${OD}_{λ} = {log}_{10} O = - {log}_{10} T = - {log}_{10} ( \frac{I}{{I}_{0}} )$$

In the formula, O represents the opacity, T represents the transmittance, I₀ represents the intensity of the incident light beam, and I represents the intensity of the outgoing light beam.

In a preferred embodiment, the light-emitting material is aligned in at least one of plural scattering states. Preferably, when the light-emitting material switches bidirectionally between the absorbing state and the transmitting state, the light-emitting material adopts the scattering state. Accordingly, since there are a plurality of positions between the transmitting state and the absorbing state, it is preferred that a plurality of scattering states exist.

In a case where a liquid crystal is used as a switchable host, the light-emitting material is embedded in the liquid crystal. That is, as the liquid crystal move, the light-emitting material also moves. In a liquid crystal gel or liquid crystal rubber, a slight amount of the mesogenic groups are still able to move. The light-emitting material is embedded in the mesogenic groups, and also moves on movement of the liquid crystal. In a transmitting position, preferably most of the incident light passes through the optical device, so the optical density is low. In the absorbing state, most of the incident light is absorbed by the light-emitting material, so the optical density is high.

In the scattering state, external light that enters the optical device are emitted from the optical device in random directions. In one preferred embodiment, the switching layer includes a liquid crystal host, and the liquid crystal is configured to have an in-plane cholesteric alignment or multiple alignments. This configuration of the liquid crystal causes variation in the refractive index over a short distance within the switching layer, thereby causing the light to be scattered.

Preferably, the incident light is absorbed and radiated by the light-emitting material in all positions of the light-emitting material. The amount of the absorbed light depends on the alignment of the light-emitting material. Preferably, the absorbed light is radiated into the light guide system, and the light guide system guides the light to the energy conversion system by total internal reflection. By use of the light guide system, the light can be transmitted with almost no loss. Therefore, the position of the energy conversion system is independent of the position of the light-emitting material. In other words, the distance between the light-emitting material and the energy conversion system is almost not important.

Preferably, the absorption axis of the light-emitting material is aligned perpendicular or approximately perpendicular to the main extension plane of the switching layer in the transmitting state. This means that all of the light transmitted through the window at a normal angle with respect to the window glass is hardly absorbed by the light-emitting material. Furthermore, the absorption axis of the light-emitting material is preferably aligned parallel or approximately parallel to the main extension plane of the switching layer in the absorbing state. Since the absorption axis of the light-emitting material can be in any position between completely parallel and completely perpendicular to the main extension plane of the switching layer, there are a plurality of positions with different degrees of opacity and/or transmissivity. It should be noted that the light-emitting material can be hardly aligned 90° (completely perpendicular) or 0° (completely parallel) with respect to the main extension plane of the switching layer. In many cases, most of the light-emitting material is aligned about 90° with respect to the main extension plane of the switching layer in the transmitting state, and is aligned about 0° with respect to the main extension plane of the switching layer in the absorbing state.

In the scattering state, the absorption axis of the light-emitting material is preferably aligned alternately between the parallel alignment and the perpendicular alignment, or aligned randomly. In a preferred embodiment, when the light-emitting material shifts from the transmitting state to the absorbing state or vice versa, the light-emitting material and/or the host attains the scattering state in a stable intermediate state.

For example, where the switching layer includes the liquid crystal, the light-emitting material and the chirality induction agent (chiral doping agent), due to supply of an alternating current from a voltage source, in a state between a high absorption state at low voltage and a low absorption state at high voltage, the optical device exhibits a scattering state at an intermediate voltage that is caused by a “fingerprint” alignment of the liquid crystal. At this moment, in a dark mode, all liquid crystal molecules have molecular axes in the plane of the switching layer. Furthermore, the liquid crystal molecules have chiral nematic ordering. This means that over the thickness of the switching layer, the direction of the molecular axis (i.e., director) rotates in the plane. Hence, for a rod-like liquid crystal, this rotation indicates a helix that has a helical axis perpendicular to the plane of the switching layer. The alignment of the light-emitting material follows the alignment of the host liquid crystal, and thus also shows a rotation over the thickness of the switching layer.

In the scattering mode, the helical axis is tilted 90° so that the director rotates in the plane of the switching layer. Accordingly, the refractive index in the plane varies during the period of half rotation of the director of the molecules. Due to this variation, scattering of the light transmitted through the switching layer occurs. In this case, the light-emitting material is configured in a helical shape in the plane of the switching layer, so there are both parallel and perpendicular alignments of the absorption axis of the molecules with respect to the plane.

In a preferred embodiment, the optical device has at least one wavelength selection mirror. The light guide system preferably includes the wavelength selection mirror. In this preferred embodiment, since the wavelength selection mirror is used on one or both sides of a main extension plane of the light guide system, more of the radiated light is confined inside the light guide system. The wavelength selection mirror is preferably an inorganic or an organic wavelength selection mirror, and/or the wavelength selection mirror preferably has transmissivity of 50% with respect to the light absorbed by the light-emitting material and reflectivity of at least 50% with respect to non-polarized light radiated from the light-emitting material. In some cases, it is favorable to dispose the wavelength selection mirror on one or both sides of the optical device, and/or above (at top) and below (at bottom) the switching layer with respect to the main extension plane of the switching layer.

The efficiency of the optical device transmitting the radiated light to the energy conversion system especially depends on the capability of the optical device to confine the radiated light inside the light guide system. Due to the capability to selectively allow light into the optical device and the capability to prevent light of other wavelength from exiting the optical device, the amount of light guided to the energy conversion system can be increased. In this case, a reflection wavelength of the wavelength selection mirror is selected such that the reflection wavelength is longer than the absorption band of the light-emitting material but the radiated light has a longer wavelength than the absorbed light and is mostly reflected by the wavelength selection mirror. In one preferred embodiment, the wavelength selection mirror can be produced using a cholesteric liquid crystal film. The cholesteric liquid crystal film reflects a maximum of 50% of light at a specific wavelength since period modulation of the refractive index causes Bragg reflection. The width of the reflection band depends on the cholesteric pitch and the birefringence of the liquid crystal. By combining a right-handed cholesteric layer and a left-handed cholesteric layer, a total reflection mirror for a specific range of wavelengths is obtained. Alternatively, by using two cholesteric layers in the same direction with a half-wave retardation layer therebetween, a total reflection mirror for a specific range of wavelengths can be obtained.

In a preferred embodiment, a polymeric wavelength selection mirror includes one or more cholesteric layers reflecting right-handed circularly polarized light or one or more cholesteric layers reflecting left-handed circularly polarized light, or includes both one or more cholesteric layers reflecting right-handed circularly polarized light and one or more cholesteric layers reflecting left-handed circularly polarized light, or includes one or more cholesteric layers reflecting light of the same rotation direction in combination with a half-wave plate.

Furthermore, the invention aims to provide a method of transmitting light through the optical device. Preferably, in the method, the light-emitting material is switched from the absorbing state to the transmitting state or vice versa by applying an electric potential with an amplitude A1, an electric field V1 and/or an intensity of light of a specific wavelength λ1 that respectively have a specific frequency f1.

Preferably, the light-emitting material is switched to the scattering state by applying an electric potential with an amplitude A2, an electric field V2 and/or an intensity of light of a specific wavelength λ2 that respectively have a specific frequency f2. The amplitudes A1 and A2 are different from each other, the electric fields V1 and V2 are different from each other, and/or the intensities of the light of the specific wavelengths λ1 and λ2 having the specific frequencies f1 and f2 respectively are different from each other. The voltage source is capable of supplying an alternating current of a sinusoidal or square-wave shape having a frequency of 10 to 10,000 Hz, preferably of 1 kHz. Control signals applied to the light guide system include square-wave signals, sinusoidal signals, sawtooth signals or trapezoidal signals, etc. When a high-level signal V1 is applied to the light guide system, the optical device exhibits high or low transmissivity. When a low-level signal V2 is applied, the optical device exhibits a scattering property. When a signal V1′ having a longer period than the signal V1 is applied, the optical device also exhibits the scattering property. When no voltage is applied, the optical device exhibits low or high transmissivity.

In one preferred embodiment where a polymer layer having electrodes is used as the alignment layer, by applying an electrical signal S1, the switching layer is brought to position 1 (e.g., the transmitting state), and by applying an electrical signal S2, the switching layer is brought to position 2 (e.g., the absorption state). For effective use, the signals S1 and S2 have different amplitude values and/or frequency values.

In one preferred embodiment, by applying a third electrical signal S3, the switching layer reaches the scattering state. The amplitude value and/or frequency value of the signal S3 is different from those of the signals S1 and S2.

In one preferred embodiment, the optical device has at least two stable states. A stable state relates to an alignment configuration of the light-emitting material that can be maintained for a long time without application of a stimulus that may be an electrical signal or an optical signal. In a case where a third position is desired, a system having three stable states is also possible. In one preferred embodiment, the stable states are obtained using a liquid crystal host as the switching layer. In this preferred embodiment, the stable state of the liquid crystals is obtained by generating a minimum free energy of the system. In order to switch to another alignment, the liquid crystals have to reorganize themselves, which causes an energy barrier that can be exceeded only by providing an external stimulus. This external stimulus may be an electric field, or a command surface functioning as the alignment layer.

The optical device is preferably used for a window, a vehicle, a building, a greenhouse, eyeglasses, safety glass, an optical instrument, a soundproof wall and/or a medical instruments. In these applications, at least the switching layer, the supporting means, the light guide system and the alignment layer are preferably replaced with sheet glass. Safety glass according to the invention is special glass that can be fogged by switching. Such glass can be used for eye protection during a process in which high light energy is generated vigorously. Such a process is, e.g., a welding process, wherein the optical device can be used as welding goggles or laser goggles in place of goggles made of glass.

Hereinafter, an example where the present optical device is applied to a window is described in details. The invention is best understood by reference to the accompanying drawings and the following description of examples. The accompanying drawings and the following description of examples are intended to describe one embodiment of the invention and should not be interpreted in any manner as limiting the scope of the invention.

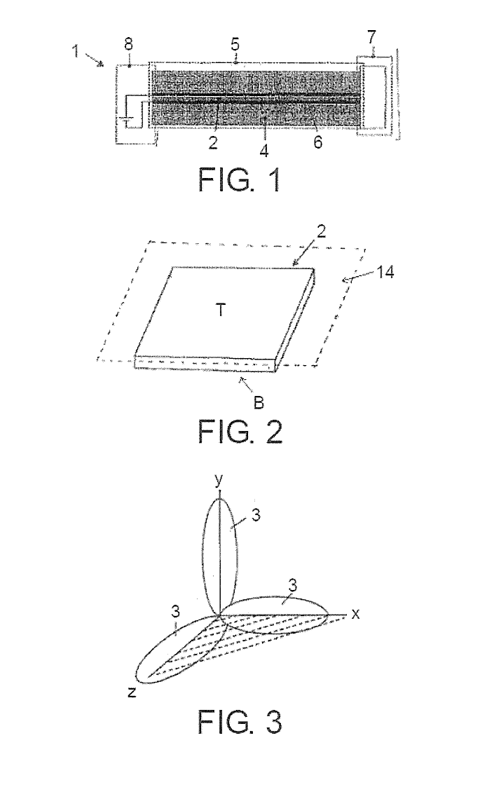

FIG. 1 shows a cross-sectional view of an optical device 1. The optical device 1 includes: a switching layer 2 including a light-emitting material 3 (not illustrated), a supporting means 4, a light guide system 5, and an energy conversion system 7. In FIG. 1, the switching layer 2 is a liquid crystal layer, and an alignment layer 6 is in contact with an inner surface of the switching layer 2. The liquid crystal layer is switched by a control system 8. The light guide system 5 may include a part of a luminescent solar concentrator. The luminescent solar concentrator (LSC) includes three main components, namely a dye layer (switching layer 2 and light-emitting material 3), a waveguide (light guide system 5) and a photovoltaic cell (energy conversion system 7). The fluorescent dye layer is used for absorbing and re-radiating (sun)light. This layer includes organic fluorescent dye molecules (light-emitting material 3), and absorbs the incident light. The absorbed light is re-radiated by fluorescence emission. The efficiency of this re-radiation process indicates quantum efficiency and may exceed 90%. The light radiated fluorescently in a direction outside of the critical angle with respect to the surface is confined in the waveguide. The light guided into the waveguide can only exit from a narrow end of the waveguide. For geometric reasons, the light that reaches an end of the waveguide automatically falls within the critical angle and thus exits. The solar concentrator is named “concentrator” because it can have a large upper surface where light enters, compared to the narrow end side where the light exits. That is, the outgoing light exhibits higher intensity (energy/unit area) than the incident light. For a waveguiding layer having a high refractive index, a transmission layer is used for guiding the light to the photovoltaic cell (energy conversion system 7). Since the photovoltaic cell is installed on the narrow end side of the waveguide, only a small photovoltaic cell is required. Nevertheless, since this photovoltaic cell is exposed to high intensity light, a large current is obtained.

FIG. 2 schematically illustrates a switching layer. The switching layer 2 preferably includes a top T and a bottom B that are parallel to each other. The surfaces of the top T and the bottom B are much larger than the thickness of the switching layer 2 perpendicular to the top T and the bottom B. Accordingly, a surface 14 parallel to the top T and the bottom B indicates the main extension plane of the switching layer 2. The alignment layer 6 is arranged along and approximately parallel to the top T and the bottom B. The energy conversion system 7 is preferably arranged approximately perpendicular to the top T and the bottom B. Inside the switching layer 2, the light-emitting material 3 is aligned approximately parallel (absorbing state) or approximately perpendicular (transmitting state) to the top A and the bottom B that are respectively parallel to the main extension plane 14.

FIG. 3 illustrates the alignments that can be adopted by the light-emitting material 3. FIG. 3 illustrates the correlation between the absorption axis of the light-emitting material 3, the propagation direction of light and the polarization direction of the electric field vector (electric field) of the incident light. Light can be illustrated as an electromagnetic wave, and the oscillation of the electromagnetic wave is perpendicular to the propagation direction of the light. In linearly polarized light, only a single oscillation plane of the electric field is present. The polarization direction is defined as the oscillation plane of the electric field of the light. Normal sunlight (isotropic light) contains components of all possible polarization directions. Herein, all possible polarization directions are equally represented. Accordingly, the isotropic light can be mathematically expressed as light having two polarization directions that are perpendicular to each other. The light-emitting material 3 is dichroic dye molecules. This means that the molecule shows stronger absorption in one direction (in the direction of the absorption axis of the molecule) than in other direction.

When the absorption axis of the molecule is perpendicular to the propagation direction of the light, and the polarization state of the light is parallel to the absorption axis of the molecule, the dye molecule exhibits high absorption. It is also possible that the absorption axis of the molecule is perpendicular to the propagation direction of the light and the polarization state of the light is perpendicular to the absorption axis of the molecule. In this case, only a small fraction of the light is absorbed. When the molecule rotates such that the propagation direction of the light is parallel to the absorption axis of the molecule, the polarization state of the light will always be perpendicular to the absorption axis of the molecule. A case where the light-emitting material 3 is aligned parallel to the Y-axis and the propagation direction of the light is parallel to the Y-axis is shown in FIG. 3. When the light-emitting material 3 is aligned parallel to the X-axis or Z-axis and isotropic (or unpolarized) light is used, the light-emitting material 3 exhibits high absorption for one polarization component of the light, namely, a polarization component parallel to the main absorption axis of the molecule. When a transmissive (lowly absorptive) optical device 1 is desired, the absorption axis of the light-emitting material 3 is aligned parallel to the Y-axis and thus perpendicular to the X-axis and Z-axis and also perpendicular to two mathematically determined polarization states of the isotropic light. The main extension plane 14 of the switching layer 2 is indicated by dashed lines. In regard to the transmissive (lowly absorptive) optical device 1, the absorption axis of the light-emitting material 3 is perpendicular to the main extension plane 14 of the switching layer 2. When the optical device 1 is in a non-transmitting state, the absorption axis of the light-emitting material 3 is parallel to the X-axis or Y-axis.

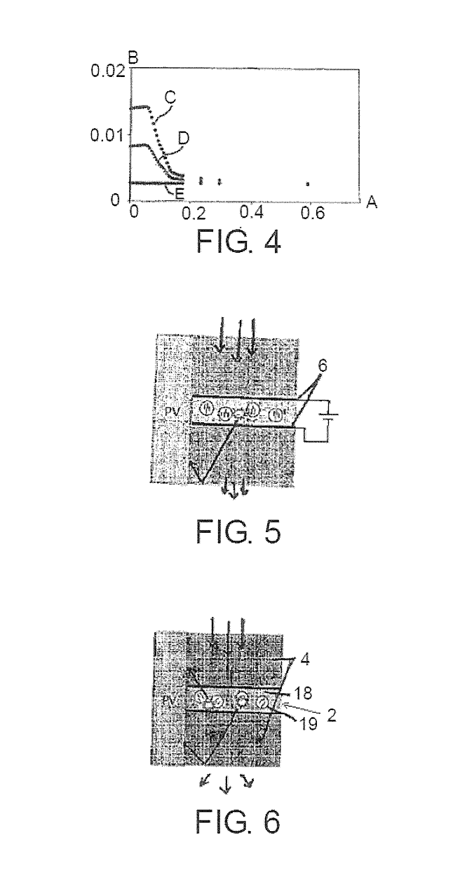

FIG. 4 illustrates the correlation between the applied voltage and the optical density of the optical device. The A-axis represents the applied voltage (V/m) and the B-axis represents the optical density per μm. Curve C represents light having a polarization direction parallel to the absorption axis of the light-emitting material 3. Curve D represents unpolarized light; curve E represents light having a polarization direction perpendicular to the absorption axis of the light-emitting material 3. When a voltage is applied to the cell (optical device 1), the voltage is increased, and the optical density of the cell is thus decreased.

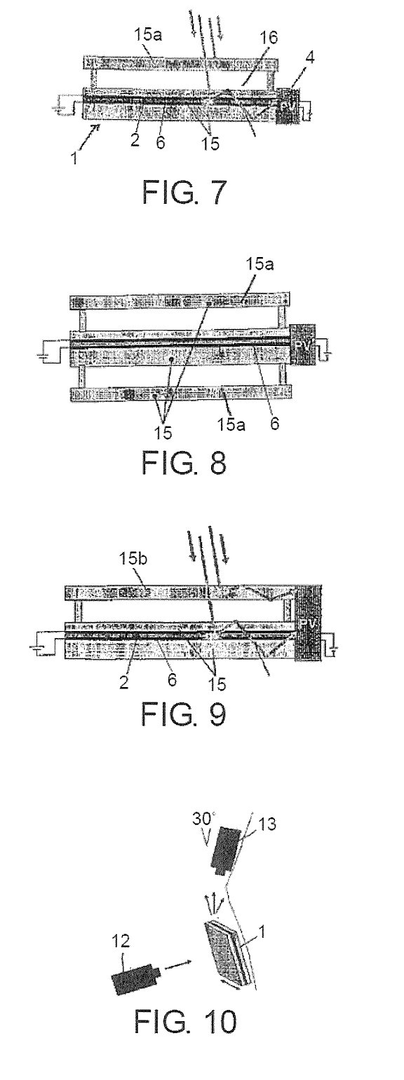

FIGS. 5 and 6 depict functions of the optical device, and FIGS. 7 to 9 depict window frames having the optical device. A polymer dispersed liquid crystal (PDLC) can also be used as the liquid crystal for the optical device according to the invention. PDLC is well-known, and many examples thereof have been published in the literature, e.g., J. W. Doane, “Polymer Dispersed Liquid Crystal Displays” (in “Liquid Crystals, Applications and Uses”), edited by B. Bahadur, World Scientific (1991), P. S. Drzaic, “Liquid Crystal Dispersions,” World Scientific (1995), and D. Coates, J. Mat. Chem., 5 (12), pp. 2063-2072, 1995.

In the PDLC, the switching layer includes a polymer matrix having droplet-shaped liquid crystals 19. The droplet-shaped liquid crystals 19 are aligned homeotropically using an electric field as in a general LCD. In most PDLC devices, the refractive index (nₚ) of the polymer matrix 18 is selected so as to match the refractive index (n_{//}) of an abnormal axis of the liquid crystals 19 and thus to not match the refractive index (n_{⊥}) of a normal axis. When an electric field is applied via an electrode that forms the alignment layer 6 and an “on” state is reached (see FIG. 5), the liquid crystal molecules 19 are aligned homeotropically. Therefore, light propagating in a direction perpendicular to the plane of the switching layer 2 does not undergo a refractive index change and thus will not be refracted. In an “off” state (see FIG. 6), the liquid crystal molecules 19 have a random alignment, and the light is refracted with a refractive index corresponding to that (n_{⊥}) of the normal axis and that of the polymer 18. As a result, the light is scattered.

In a preferred embodiment, the light-emitting material 3 of low concentration (0.5 to 5 wt %) is mixed in the switching layer 2 (the polymer matrix 18 and/or the liquid crystals 19). The light-emitting material 3 may be an anisotropic fluorescent dye aligned with the droplet-shaped liquid crystals 19, e.g., Lumogen® F Yellow 083 produced by BASF SE. Due to the light-emitting material 3, a small amount of light to be absorbed and re-radiated into the waveguide is generated. By changing the alignment of the light-emitting material 3 in the mobile phase (liquid crystals 19), light absorption by means of the light-emitting material in the switching layer 2 can be changed. In the homeotropic “on” state (FIG. 5), the absorption by the light-emitting material is low, while in the “off” state (FIG. 6), the absorption by the light-emitting material is high. The radiated or scattered light can be confined in the waveguide in the optical device 1. The light guided into the waveguide can then be converted into electrical energy by the energy conversion system 7 (e.g., a photovoltaic element (PV)) that is installed on an end of the waveguide “sandwich.” The scattering of the light in the switching layer 2 in the “off” state increases the amount of light propagating within the waveguide over a short distance, but decreases the amount of light propagating within the waveguide over a long distance.

A fluorescent perylene dye, Lumogen F 170 produced by BASF SE, exhibits strong dichroic absorption. That is, Lumogen F 170 has higher optical density for light having a polarization direction parallel to the long axis of the molecule than for light having a polarization direction perpendicular to the long axis of the molecule. The measured dichroism of a planar antiparallel cell filled with 0.1 wt % of Lumogen F 170 dissolved in the E7 host shows a dichroic ratio of 5.1.

There are many well-known methods for producing a PDLC, such as polymerization induced phase separation (PIPS), temperature induced phase separation (TIPS), and solvent induced phase separation (SIPS), etc. This specification describes the PIPS method, but the other methods may also be used to produce the same device.

The manufacture of the PDLC is started by using a homogeneous mixture of a reactive monomer (e.g., an acrylate or thiol-ene system) and a liquid crystal. Suitable commercially available materials include a mixture of an optical adhesive NOA 65 (produced by Norland Products Inc.) as a prepolymer and a liquid crystal mixture BL03 (produced by Merck & Co., Inc.) in a weight ratio of 50:50. Alternatively, a prepolymer Licrilite® PN 393 (produced by Merck & Co., Inc.) may be mixed with a liquid crystal mixture TL203 (produced by Merck & Co., Inc.) in a weight ratio of 20:80 for use. The light-emitting material 3 is homogeneously dissolved or dispersed in the mixture.

The subsequent preparation steps conform to the conventional preparation of a well-known PDLC mixture and include: preparing two substrates (polymer plates or glass plates) coated with a transparent conductor, applying the mixture on the substrates, ensuring that the mixture is applied on the substrates in a correct thickness by bar coating, by doctor blade coating or by a glass cell that uses spacers, exposing the mixture to an adjusted radiation dosage of UV light under adjusted temperature conditions so as to cause phase separation, and performing post-curing if necessary.

Optimal scattering occurs when the drop size is 1 to 2 μm. In the optical device 1 in the “on” state, for example, the transparency of the window depends on the amount of the liquid crystal material phase separated out of the prepolymer mixture. The film thickness is not defined but is generally 10 to 40 μm. The system is switched by applying a voltage (AC) over the entire film.

Many variations of PDLC systems are known to persons skilled in the art. For example, there is known a reverse mode PDLC that switches from the transmitting state (“off”) to the non-transmitting state (“on”).

In one embodiment, the optical device 1 is integrated into a window and a frame (see FIGS. 7 to 9). For example, the optical device 1 is part of a double window or a triple window (see FIGS. 7 and 8). A not-switchable glass plate is preferably arranged at a side (outside) where the majority of the light enters. A first glass layer 15a may include optical functions such as a UV filter or NIR filter, etc. In this way, the optical device 1 can be protected from harmful radiation, and the incident radiation can be further controlled. Between the first glass layer 15a and the optical device 1, a material having low thermal conductivity, such as a gas (air, argon) or a liquid or a solid or the like, is used to function as an insulating layer 16. This insulating layer 16 increases the resistance of the window to thermal conduction between the inside and the outside. In FIGS. 7 and 8, the energy conversion system 7 (photovoltaic element) is shown at one side of a glass 15, but may be disposed at any side of the glass 15.

In a second embodiment (FIG. 9), a second static (i.e., non-switching) layer 15b is a luminescent solar concentrator. The luminescent solar concentrator is well known (e.g., see Van Sark et al., OPTICS EXPRESS, December 2008, Vol. 16, No. 26, 2177322). In this embodiment, it is favorable to optically connect the energy conversion system 7 (photovoltaic element) to the glass 15 and the second static layer 15b.

### EXAMPLES

Hereinafter, the invention is described more specifically with examples. The accompanying drawings and the description of the following examples are intended to describe one embodiment of the invention and should not be interpreted in any manner as limiting the scope of the invention.

[Synthesis of Polyorganosiloxane]

The weight-average molecular weight (Mw) in the following synthesis examples is a polystyrene-converted value measured by gel permeation chromatography (GPC) under the following conditions.

Column: TSKgelGRCXLII made by Tosoh Corporation

Solvent: tetrahydrofuran, or an N,N-dimethylformamide solution containing lithium bromide and phosphoric acid

Temperature: 40° C.

Pressure: 68 kgf/cm²

### Synthesis Examples of (A) Polyorganosiloxane

### Synthesis Example A-1

### Synthesis Example According to Production Method 1

11.3 g of oxalic acid and 24.2 g of ethanol were placed in a reaction vessel equipped with a stirrer, a thermometer, a dripping funnel and a reflux cooling pipe, and stirred to prepare an ethanol solution of oxalic acid. Next, the solution was heated to 70° C. under a nitrogen atmosphere, followed by dripping of a mixture of 12.3 g of tetraethoxysilane and 2.2 g of dodecyltriethoxysilane as a silane compound. After the dripping was completed, the resultant was maintained at 70° C. for 6 hours and then cooled to 25° C. Next, by addition of 40.0 g of butyl cellosolve, a solution containing polyorganosiloxane (A−1) was prepared. The Mw of the polyorganosiloxane (A−1) contained in this solution was 12,000.

### Synthesis Example A-2

### Synthesis Example According to Production Method 2

45.2 g of propylene glycol monomethyl ether, 18.8 g of tetraethoxysilane and 3.3 g of dodecyltriethoxysilane were placed in a reaction vessel equipped with a stirrer, a thermometer, a dripping funnel and a reflux cooling pipe, and stirred to prepare a mixed solution of a silane compound. Next, the solution was heated to 60° C., followed by dripping of an oxalic acid solution including 8.8 g of water and 0.1 g of oxalic acid. After the dripping was completed, the solution was heated at 90° C. for 3 hours and then cooled to room temperature. Next, 76.2 g of butyl cellosolve was added to prepare a solution containing polyorganosiloxane (A-2). The Mw of the polyorganosiloxane (A-2) contained in this solution was 11,000.

### Synthesis Example A-3

### Synthesis Example According to Production Method 4

### Hydrolysis and Condensation Reactions of Silane Compound

246.4 g of 2-(3,4-epoxycyclohexyl)ethyltrimethoxysilane (ECETS) as a silane compound, 1,000 g of methyl isobutyl ketone as a solvent and 10.0 g of triethylamine as a catalyst were placed in a reaction vessel equipped with a stirrer, a thermometer, a dripping funnel and a reflux cooling pipe, and mixed at room temperature. Next, 200 g of deionized water was dripped by the dripping funnel for 30 min, and then a reaction was conducted at 80° C. for 6 hours while stirred under reflux. After the reaction was completed, an organic layer was taken out and washed with 0.2 wt % of an ammonium nitrate aqueous solution until the water after washing became neutral. Then, the solvent and water were distilled off under reduced pressure to obtain a polyorganosiloxane having an epoxy group as a viscous transparent liquid.

The polyorganosiloxane was subjected to ¹H-NMR analysis. A peak attributed to the epoxy group was observed around a chemical shift (6) of 3.2 ppm corresponding to the theoretical intensity. It was thus confirmed that an epoxy group side reaction did not occur during the reaction.

### [Reaction Between Polyorganosiloxane Having an Epoxy Group and a Specific Carboxylic Acid]

The polyorganosiloxane having an epoxy group obtained in the above manner, 60.0 g of methyl isobutyl ketone as a solvent, 82.3 g of 4-(4-pentyl-cyclohexyl)-benzoic acid (equivalent to 30 mol % relative to the epoxy group in the polyorganosiloxane) as a specific carboxylic acid), and 0.10 g of UCAT18X (trade name, produced by SanApro, as a curing accelerator for epoxy compounds) as a catalyst were placed in a 500 mL three-necked flask, and reacted while stirred at 100° C. for 48 hours. After the reaction was completed, an organic layer obtained by adding ethyl acetate to the reaction mixture was washed 3 times with water, and dried over magnesium sulfate. Then, the solvent was distilled off to obtain 261.2 g of a polyorganosiloxane (A-3). The Mw of the polyorganosiloxane (A-3) was 6,500.

### Synthesis Examples of Polyorganosiloxane for Horizontal Alignment Film

### Synthesis Example A-4

11.3 g of oxalic acid and 24.2 g of ethanol were placed in a reaction vessel equipped with a stirrer, a thermometer, a dripping funnel and a reflux cooling pipe, and stirred to prepare an ethanol solution of oxalic acid. Next, the solution was heated to 70° C. under a nitrogen atmosphere, followed by dripping of a mixture of 12.3 g of tetraethoxysilane and 2.2 g of methyltriethoxysilane as a silane compound. After the dripping was completed, the resultant was maintained at 70° C. for 6 hours and then cooled to 25° C. Next, by addition of 40.0 g of butyl cellosolve, a solution containing polyorganosiloxane (A-4) was prepared. The Mw of the polyorganosiloxane (A-4) contained in this solution was 10,000.

### Synthesis Example A-5

246.4 g of 2-(3,4-epoxycyclohexyl)ethyltrimethoxysilane (ECETS) as a silane compound, 1,000 g of methyl isobutyl ketone as a solvent and 10.0 g of triethylamine as a catalyst were placed in a reaction vessel equipped with a stirrer, a thermometer, a dripping funnel and a reflux cooling pipe, and mixed at room temperature. Next, 200 g of deionized water was dripped by the dripping funnel for 30 min, and then reacted at 80° C. for 6 hours while stirred under reflux. After the reaction was completed, an organic layer was taken out and washed with 0.2 wt % of an ammonium nitrate aqueous solution until the water after washing became neutral. Then, the solvent and water were distilled off under reduced pressure, so as to obtain polyorganosiloxane (A-5) having an epoxy group as a viscous transparent liquid.

### Preparation of Liquid Crystal Aligning Agent

### Preparation Example 1

To a solution containing the polyorganosiloxane (A−1) obtained in Synthesis Example A-1 as polyorganosiloxane, butyl cellosolve was added as a solvent to obtain a solution having a solid content concentration of 5.0 wt %. This solution was filtered using a filter having a hole size of 1 μm, so as to prepare a liquid crystal aligning agent (A−1).

### Preparation Example 2

Except that the polyorganosiloxane (A-2) obtained in Synthesis Example A-2 was used as the polyorganosiloxane, a liquid crystal aligning agent (A-2) was prepared in the same manner as in Preparation Example 1.

### Preparation Example 3

Except that the polyorganosiloxane (A-3) obtained in Synthesis Example A-3 was used as the polyorganosiloxane, a liquid crystal aligning agent (A-3) was prepared in the same manner as in Preparation Example 1.

### Preparation Example 4

Except that the polyorganosiloxane (A-4) obtained in Synthesis Example A-4 was used as the polyorganosiloxane, a liquid crystal aligning agent (A-4) was prepared in the same manner as in Preparation Example 1.

### Preparation Example 5

Except that the polyorganosiloxane (A-5) obtained in Synthesis Example A-5 was used as polyorganosiloxane, a liquid crystal aligning agent (A-5) was prepared in the same manner as in Preparation Example 1.

### Comparative Example 1

An optical device was fabricated in the following procedure.

1. A commercially available glass liquid crystal cell was obtained from Linkam Scientific Instruments. Ltd. or Instec Inc. The liquid crystal cell has on its inner surface a thin-film (100 nm)-based transparent electrode of ITO (indium tin oxide). The cell gap between the upper cover and the lower cover of the glass cell is 20 μm.

2. A light transmissive alignment layer was disposed on the inner surface of the glass cell. This alignment layer was obtained by rubbing a polyimide layer that was formed using a liquid crystal aligning agent AL90101 produced by JSR Corporation with a cloth and has a uniaxial planar alignment.

3. A fluorescent perylene dye Lumogen® F Yellow 170 produced by BASF SE of a low concentration (0.1 wt %) as the light-emitting material was mixed with a liquid crystal mixture E7 (produced by Merck & Co., Inc.) to prepare a fluorescent liquid crystal mixture.

4. Next, a small amount of the fluorescent liquid crystal mixture was injected into the cell, and filled the glass cell up to its opened side by a capillary action.

5. A photovoltaic cell was used as an energy conversion system. An optical adhesive UVS 91 produced by Norland Products Inc., which conformed to the refractive index of the glass, was optically attached to a side portion of the glass. The photovoltaic cell is disposed to face a waveguide (light guide pipe) made of glass.

6. A voltage-variable voltage source was attached to the electrode, and an alternating current (AC) of a sinusoidal or square shape having a frequency of 1 kHz was supplied from the voltage source.

The absorbed light, the radiated light and the guided light were measured. The measurement was performed by measuring a minimum light output in the side portion of the glass cell. The light was radiated from a light source (12) and entered the optical device (1), and was then outputted from the light guide pipe, so as to be observed by a photodetector (13) (see FIG. 10). The guided light was observed by the photodetector (13) disposed at an angle of 30 degrees with respect to the cell plane. The spectrum output of the guided light was approximately consistent with a fluorescence spectrum of the dye molecules. In addition, when the applied voltage was raised, the optical density of the cell decreased, and the output at a cell end increased. From the above, it is known that the optical device (solar concentrator) operates normally.

### Comparative Example 2

Except that a small amount of a chirality induction agent (chiral doping agent) was added in step 3 of Comparative Example 1, the same operation as in Comparative Example 1 was carried out.

3. 5 wt % of CB15 produced by Merck & Co., Inc. was added and mixed with the fluorescent liquid crystal mixture as prepared in Comparative Example 1.

In this window, a high absorption state was achieved at a low voltage, and a low absorption state was achieved at a high voltage. In the state between the high absorption state at the low voltage and the low absorption state at the high voltage, the window exhibited the scattering state at intermediate voltage caused by the “fingerprint” alignment of the liquid crystal. In all states, the window was capable of functioning as a luminescent solar collector to collect light. As the applied voltage is raised, this window is shifted in an order of a dark mode, a scattering mode, and a light mode. In a transmission mode, all the molecules are aligned perpendicular to the plane of the switching layer, and no chiral configuration of liquid crystals is allowed.

### Comparative Example 3

Except that a different molecular alignment layer was selected in step 2 in Comparative Example 1 and the composition of the fluorescent liquid crystal mixture was changed in step 3, the same operation as in Comparative Example 1 was carried out.

2. A light transmissive alignment layer was provided on the inner surface of the glass cell. At least one of the two substrates has a homeotropic alignment (wherein the angle of the molecular director with respect to the substrate is about 90°). This alignment layer is obtained by lightly rubbing a polyimide layer that is formed using a liquid crystal aligning agent JALS-204 produced by JSR Corporation to provide an alignment offset of several degrees (typically 2°) from the normal.

3. The fluorescent liquid crystal mixture was prepared using a liquid crystal mixture MLC6610 (produced by Merck & Co., Inc.) having a dielectric anisotropy of −3.1 as a liquid crystal having a negative dielectric anisotropy. A fluorescent dye was added to the mixture in a low concentration (typically 0.1 wt %). Moreover, the liquid crystal having a negative dielectric anisotropy may alternatively be AMLC-0010 (produced by AlphaMicron, Inc.) that has a dielectric anisotropy of −3.7.

At zero or low voltage, this window was in a highly transmissive state, and reached a scattering state when the voltage applied to the transparent electrode was raised. At the high voltage, a dark state was reached. In all states, the photovoltaic cell collected sunlight that was converted into electrical energy.

### Examples 1 and 2

Except that the layers obtained by the liquid crystal aligning agents (A-4) and (A-5) were respectively used as the alignment layers in Comparative Examples 1 and 2, the same evaluation as that in Comparative Examples 1 and 2 was carried out, and the results obtained were equivalent to those of Comparative Examples 1 and 2.

### Examples 3 to 5

Except that the layers obtained by the liquid crystal aligning agents (A−1) to (A-3) were respectively used as the alignment layer in Comparative Example 3, the same evaluation as that in Comparative Example 3 was carried out, and the results obtained were equivalent to that of Comparative Example 3.

[Light Resistance Test]

The optical devices fabricated in Examples 1 to 5 and Comparative Examples 1 to 3 were subjected to a 5,000-hour irradiation experiment in a weather meter with a carbon arc as a light source, and the dark state and the highly transmissive state of each optical device were observed by eyes. As a result, no variation was observed in the optical devices in Examples 1 to 5 as compared to prior to the light resistance test, while alignment disorder was observed in the optical devices in Comparative Examples 1 to 3. This shows that the optical device of the invention has excellent light resistance.

What is claimed is:

1. An optical device, comprising:
a switching layer, comprising an anisotropic light-emitting material for absorbing and radiating light, and switching alignment of the light-emitting material;
an alignment layer in contact with the switching layer;
an optical energy conversion means, converting radiated light into at least one energy form selected from heat and electricity; and
a light guide system in physical contact with the optical energy conversion means and guiding the radiated light to the optical energy conversion means, wherein
the switching layer controls transmission of light through the optical device, and
the alignment layer comprises 80 wt % or more of a polyorganosiloxane.

2. The optical device of claim 1, wherein the polyorganosiloxane is a polymer obtained by hydrolysis and condensation reactions of a silane compound.

3. The optical device of claim 1, wherein the polyorganosiloxane is a polymer obtained by a reaction in presence of a dicarboxylic acid and an alcohol.

4. The optical device of claim 1, wherein the polyorganosiloxane has a group represented by formula (A-1), 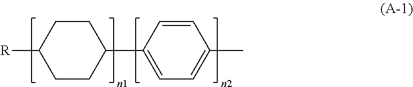
wherein n1 is an integer of 0 to 2, and n2 is 0 or 1; when n1+n2 is 2 or greater, R is a hydrogen atom, alkyl having 1 to 20 carbons, or fluoroalkyl having 1 to 20 carbons; and when n1+n2 is 0 or 1, R is a group having a steroid structure, alkyl having 4 to 20 carbons, or fluoroalkyl having 2 to 20 carbons.

5. The optical device of claim 1, wherein the polyorganosiloxane has an epoxy group.

6. Use of the optical device of claim 1 for a window, a vehicle, a building, a greenhouse, eyeglasses, safety glass, an optical instrument, a soundproof wall, or a medical instrument.
